(19) United States
(12) Patent Application Publication
(10) Pub. No.: US 2026/0148411 A1
(43) Pub. Date: May 28, 2026

(54) Methods And Systems Of Film Frame Pre-Alignment For Semiconductor Measurement Equipment

(71) Applicant: KLA Corporation, Milpitas, CA (US)

(72) Inventors: Avner Safrani, Mitzpe Aviv (IL); Andrey Yakovlev, Haifa (IL); Gal Alon, Haifa (IL); Ivan Osaulenko, Migdal Ha-Emeq (IL)

(21) Appl. No.: 19/323,310

(22) Filed: Sep. 9, 2025

Related U.S. Application Data
(60) Provisional application No. 63/726,256, filed on Nov. 28, 2024.

(51) Int. Cl. G06T 7/73; G01B 11/27; G06T 7/00; H01L 21/68; H04N 23/56; H04N 25/71

(52) U.S. Cl. CPC G06T 7/73; G01B 11/272; G06T 7/0004; H04N 23/56; H04N 25/71; H10P 72/50; G06T 2207/30148

(57) ABSTRACT

Methods and systems for high precision, high throughput measurement of devices mounted to a Film Frame (FF) are described herein. A pre-alignment system precisely measures the position and orientation of both a film frame and a wafer supported by the film frame with respect to a coordinate system fixed to a measurement system employed to characterize devices under measurement. In this manner, the film frame and the wafer supported by the film frame are loaded onto a measurement system chuck with a known orientation and position with respect to the measurement system. Precise knowledge of position and orientation of the film frame and wafer enables measurement system navigation through wafer sites with minimal throughput loss as additional search and alignment sequences are generally not required. In preferred embodiments, a pre-alignment system is integrated with a measurement system to perform pre-alignment functionality within a shared equipment footprint.

### CROSS REFERENCE TO RELATED APPLICATION

The present application for patent claims priority under 35 U.S.C. § 119 from U.S. provisional patent application Ser. No. 63/726,256, filed Nov. 28, 2024, entitled, “A Method for Film Frame Carrier Pre Alignment,” the subject matter of which is incorporated herein by reference in its entirety.

### TECHNICAL FIELD

The described embodiments relate to systems for packaged device inspection, metrology, or both, and more particularly to packaged semiconductor device inspection and metrology modalities.

### BACKGROUND INFORMATION

Semiconductor devices such as logic and memory devices are typically fabricated by a sequence of processing steps applied to a substrate or wafer. The various features and multiple structural levels of the semiconductor devices are formed by these processing steps. For example, lithography among others is one semiconductor fabrication process that involves generating a pattern on a semiconductor wafer. Additional examples of semiconductor fabrication processes include, but are not limited to, chemical-mechanical polishing, etch, deposition, and ion implantation. Multiple semiconductor devices may be fabricated on a single semiconductor wafer and then separated into individual semiconductor devices by a process commonly referred to as die singulation. Singulated semiconductor devices are subsequently tested and packaged. In general, one or more singulated semiconductor devices are packaged into a casing that protects the semiconductor devices from the operating environment, facilitates heat removal, and provides facilities for electrical interconnection of the semiconductor device with the application environment.

The semiconductor industry has implemented advanced packaging techniques to connect multiple semiconductor devices, a.k.a., integrated circuits, chips, die, etc., into an integrated, compact system package. Advanced packaging processing techniques enable fabrication of electronic systems with enhanced processing speed and dramatically reduced physical size. As such, advanced packaging techniques are proliferating in the semiconductor fabrication industry.

Advanced packaging techniques include multiple fabrication processes, including plasma dicing of molded dies. Plasma dicing has replaced legacy saw dicing techniques in advanced packaging processes because plasma dicing generates a very smooth, clear die edge cut. This high quality cut is required to meet the extreme cleanliness requirements of an advanced packaging process and to enable precise interconnection of multiple dies.

The plasma dicing process is implemented on a wafer mounted to a film frame (FF) support structure. The FF supports the wafer, before, during, and after the plasma process. For example, the FF enables handling of the wafer during inspection processes performed before and after a plasma dicing process step.

FIG. 1 is a top view of a simplified diagram illustrative of a typical FF 10 supporting a wafer 13. FIG. 2 is a cross-sectional view of FF 10 at the cross-section A-A depicted in FIG. 1. As depicted in FIGS. 1 and 2, FF 10 includes a perimeter frame 11 that is typically fabricated from a structurally rigid material, e.g., aluminum, stainless steel, various polymer based materials, etc. A layer of support material 12, e.g., a thin, polymer based material, is stretched across, and held in place by, perimeter frame 11. A thin, adhesive film 14 is spread across the top facing side of support material 12. Wafer 13 is held in place by adhesive material 14. Wafer 13 can be a whole wafer, e.g., before the plasma dicing process, a diced wafer, e.g., after the plasma dicing process. In another example, wafer 13 can be a reconstructed wafer, e.g., individual dies that have been placed on adhesive material 14 individually for subsequent processing steps, e.g., inspection. In many examples of a reconstructed wafer, the individual dies are arranged in rows in a spatially periodic manner to emulate all or part of a diced wafer.

Measurements, including both inspection and metrology processes, are used at various steps during a semiconductor manufacturing process, including advanced packaging processes. Inspection and metrology involves a wide array of checks on package integrity, including geometric dimensions, structural integrity, electrical performance, etc., to promote higher packaged device yield. However, as design rules shrink in size and package complexity increases, inspection and metrology systems are required to capture a wider range of physical defects while maintaining high throughput.

Traditionally, FFs are transferred to an inspection tool directly from a film frame carrier device, e.g., a front opening unified pod (FOUP). In some examples, FFs are transferred to an inspection tool manually. Without accurate pre-alignment, the inspection tool must spend a significant amount of time and computational effort to discover the location and orientation of the wafer within the inspection tool coordinate system before successful navigation and inspection can begin. In some examples, the location and orientation of the wafer within the inspection tool coordinate system is so far offset, the inspection tool cannot successfully navigate and inspect the entire wafer, and the wafer must be unloaded and reloaded onto the inspection tool in an attempt to reduce the location and orientation offsets. This causes additional loss of time and additional computational effort. As a result, current systems for loading inspection tools with FFs result in a significant negative impact on overall inspection tool throughput.

Inspection systems are used extensively in advanced packaging process flows within the semiconductor industry to detect device and packaged device defects. Improvements in overall handling and inspection process throughput are desired. More specifically, it is desirable to locate a wafer onto the wafer chuck of an inspection system with accurate knowledge of position and orientation of the wafer with respect to the inspection tool positioning system such that inspection can be initiated with a minimum amount of time and effort required to discover the alignment of the wafer with respect to the inspection system.

### SUMMARY

Methods and systems for high precision, high throughput measurement of devices mounted to a Film Frame (FF) are described herein. More specifically, a pre-alignment system is employed to measure and correct for orientation and location errors that limit throughput of existing measurement systems operating on whole wafers, diced wafers, and reconstructed wafers. In preferred embodiments, a pre-alignment system is integrated with a measurement system to perform pre-alignment functionality within a shared equipment footprint.

A pre-alignment system precisely measures the position and orientation of both a film frame and a wafer supported by the film frame with respect to a coordinate system fixed to a measurement system employed to characterize devices under measurement. In this manner, the film frame and the wafer supported by the film frame are loaded onto a measurement system chuck with a known orientation and position with respect to the measurement system. Precise knowledge of position and orientation of the film frame and wafer enables measurement system navigation through wafer sites with minimal throughput loss as additional search and alignment sequences are generally not required.

In one aspect, a semiconductor measurement system, e.g., a semiconductor inspection system, a semiconductor metrology system, etc., includes a pre-alignment system configured to estimate the position and orientation of a film frame and a wafer mounted to the film frame relative to the measurement system.

In another aspect, a pre-alignment system is employed to estimate a location of a FF and a location and orientation of a wafer mounted to the FF with respect to a system coordinate frame based on one or more images captured by the pre-alignment system.

In one further aspect, a background masking algorithm is employed to mask off background features from a wafer and background features of a FF. Depending on image quality and wafer cleanliness, background masking is optional.

In another further aspect, a course edge detection algorithm is executed on a collected image after background masking, if background masking is performed. The course edge detection algorithm captures critical features such as the wafer edge and inner edge of the perimeter frame, and optionally, dicing lines. However, in addition to critical features, coarse edge detection may also detect spurious features such as non-circular edge structures, dicing residue, etc. In these examples, a secondary masking algorithm is executed to mask off the spurious features.

In another further aspect, a fine edge detection algorithm is executed on a collected image after secondary masking. The fine edge detection algorithm captures critical features such as the wafer edge and inner edge of the perimeter frame, and optionally, dicing lines with high spatial resolution with a minimum of spurious features. In general, masking and detection can be iterated until critical features are captures without spurious features.

In another further aspect, a circle fitting algorithm is executed on an identified image segment indicative of the edge of a wafer and to an identified image segment indicative of the inner edge of a perimeter frame. The circle fitting algorithm estimates the location of the geometric center of the wafer and the location of the geometric center of the inner edge of the perimeter frame in image space.

In another further aspect, the estimated locations of the location of the geometric center of the wafer and the inner edge of the perimeter frame are converted from image space to the reference measurement system coordinate space coordinate frame.

In another further aspect, a pattern recognition algorithm is executed to identify the location of a notch structure purposely integrated with the edge of a wafer, and determine the orientation of the wafer with respect to the measurement system coordinate space based on the location of the notch structure and an identified image segment indicative of the edge of the wafer.

In some other examples, the notch structure is not present or is significantly distorted by a dicing process such that the orientation angle cannot be determined. In these examples, the orientation of a wafer in measurement system coordinate space is determined based on identified dicing lines on a diced or reconstructed wafer.

In another aspect, a pre-alignment system is employed to estimate a location of a FF and a location and orientation of a wafer mounted to the FF with respect to a system coordinate frame based on multiple images captured by the pre-alignment system, each collected at different orientations of the wafer and FF with respect to the measurement system coordinate frame.

The foregoing is a summary and thus contains, by necessity, simplifications, generalizations and omissions of detail; consequently, those skilled in the art will appreciate that the summary is illustrative only and is not limiting in any way. Other aspects, inventive features, and advantages of the devices and/or processes described herein will become apparent in the non-limiting detailed description set forth herein.

### BRIEF DESCRIPTION OF THE DRAWINGS

FIG. 1 is a top view of a simplified diagram illustrative of a typical film frame supporting a wafer.

FIG. 2 is a cross-sectional view of the film frame at the cross-section A-A depicted in FIG. 1.

FIGS. 3A-D depict an exemplary semiconductor measurement system including a pre-alignment system 120 in four different configurations.

FIG. 4 is a simplified diagram illustrative of a Film Frame (FF) pre-alignment system in one embodiment.

FIG. 5 is a simplified diagram illustrative of an image of a whole wafer collected by a camera of a pre-alignment system.

FIG. 6 is a simplified diagram illustrative of the estimated locations of the center of a wafer in image space for N different collected images.

FIG. 7 is a simplified diagram illustrative of the estimated locations of the center of a film frame in image space for N different collected images.

FIG. 8 is a simplified diagram illustrative of an image of a whole wafer including a notch structure collected by a camera of a pre-alignment system.

FIG. 9 is a simplified diagram illustrative of an image of a diced wafer collected by a camera of a pre-alignment system.

FIG. 10 is a simplified diagram illustrative of a Film Frame (FF) pre-alignment system in another embodiment.

FIG. 11 is a simplified diagram illustrative of a Film Frame (FF) pre-alignment system in another embodiment.

FIG. 12A is an image illustrative of a whole wafer collected by a camera of a pre-alignment system after background masking, course edge detection, secondary masking, and fine edge detection.

FIG. 12B is an image illustrative of a diced wafer collected by a camera of a pre-alignment system after background masking, course edge detection, secondary masking, and fine edge detection.

FIG. 12C is an image indicative of a notch structure identified in an image collected by a pre-alignment system.

FIG. 12D is an image indicative of diced lines identified in an image collected by a pre-alignment system in one example.

FIG. 13 illustrates a flowchart of an exemplary method for pre-alignment of film frames in at least one novel aspect.

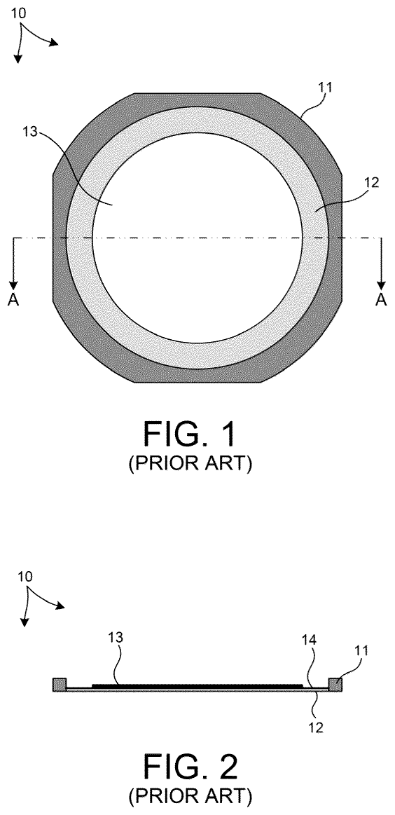

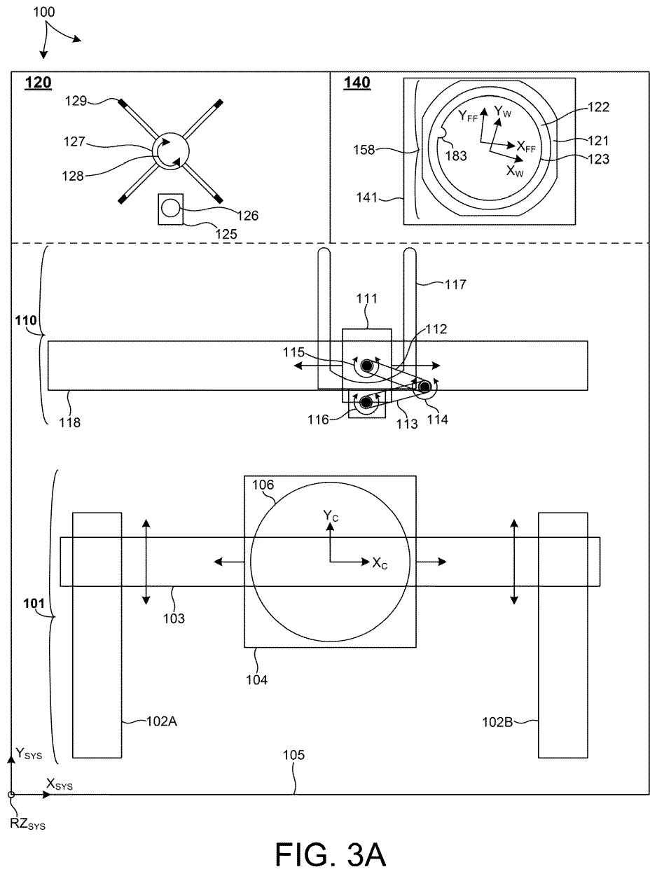

### DETAILED DESCRIPTION

Reference will now be made in detail to background examples and some embodiments of the invention, examples of which are illustrated in the accompanying drawings.

Methods and systems for high precision, high throughput measurement of devices mounted to a film frame are described herein. More specifically, a pre-alignment system is employed to measure and correct for orientation and location errors that limit throughput of existing measurement systems operating on whole wafers, diced wafers, and reconstructed wafers. In preferred embodiments, a pre-alignment system is integrated with a measurement system to perform pre-alignment functionality within a shared equipment footprint.

A pre-alignment system precisely measures the position and orientation of both a film frame and a wafer supported by the film frame with respect to a coordinate system fixed to a measurement system employed to characterize devices under measurement. In some embodiments, the pre-alignment system is able to measure the position of a film frame and a wafer supported by the film frame with respect to a measurement system coordinate frame within 50 micrometers, or less. Similarly, the pre-alignment system is able to measure the orientation of a film frame and a wafer supported by the film frame with respect to a measurement system coordinate frame within 50 millidegrees, or less. In this manner, the film frame and the wafer supported by the film frame are loaded onto a measurement system chuck with a known orientation and position with respect to the measurement system. Precise knowledge of position and orientation of the film frame and wafer enables measurement system navigation through wafer sites with minimal throughput loss as additional search and alignment sequences are generally not required.

In one aspect, a semiconductor measurement system, e.g., a semiconductor inspection system, a semiconductor metrology system, etc., includes a pre-alignment system configured to estimate the position and orientation of a film frame and a wafer mounted to the film frame relative to the measurement system.

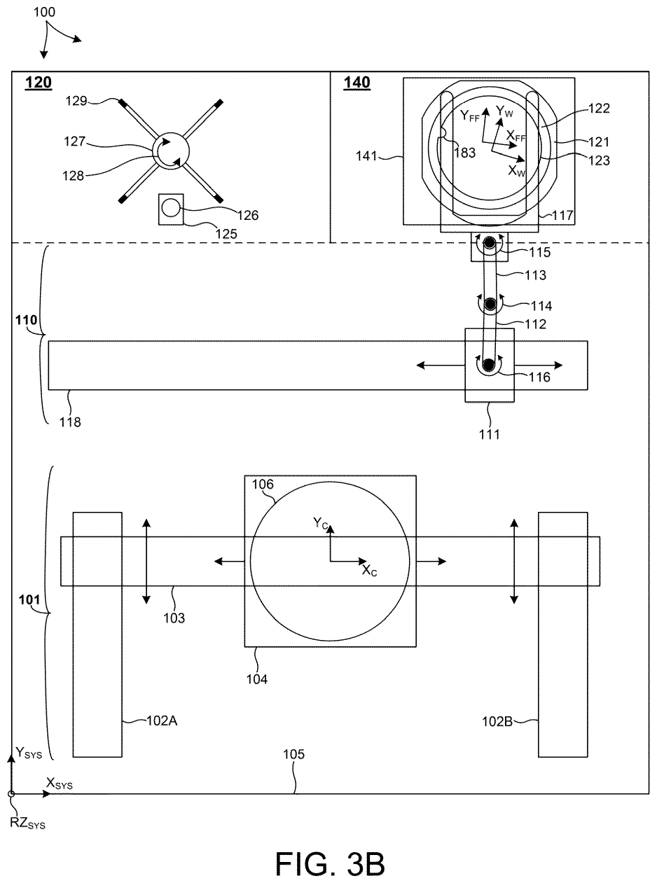

FIGS. 3A-D depict an exemplary semiconductor measurement system 100 including a pre-alignment system 120 in one embodiment.

As depicted in FIG. 3A, semiconductor measurement system 100 includes a system frame 105, measurement positioning stage 101, transfer robot 110, a pre-alignment system 120, and load port 140. As depicted in FIG. 3A, a measurement system coordinate frame, {X_{SYS},Y_{SYS}}, is attached to system frame 105. In general, a measurement system coordinate frame may be attached at any fixed with respect to system frame 105 as a reference for location and orientation of any components moving with respect to system frame 105. Components of a measurement system employed to inspect or measure wafers, e.g., measurement system illumination sources, optics, and detectors, are mounted to system frame 105. Thus, movements with respect to system frame 105 are equivalent to movements with respect to the measurement system employed to inspect or measure wafers.

Positioning stage 101 is employed to control the position and orientation of measurement chuck 106 with respect to system frame 105 and the attached measurement system coordinate frame, {X_{SYS},Y_{SYS}}. In the embodiment depicted in FIGS. 3A-D, the Xc-Yc coordinate system is fixed to measurement chuck 106, for example, at the center of measurement chuck 106. In general, the Xc-Yc coordinate system depicted in FIGS. 3A-D may be located in any suitable location on the surface of measurement chuck 106.

Positioning stage 101 includes two linear motion modules 102A-B including bearing elements, e.g., linear bearings, sets of roller bearings, etc., mounted between system frame 105 and intermediate motion module 103. The bearing elements constrain the motion of intermediate motion module 103 with respect to system frame 105 to the Yc direction. In addition, linear motion modules 102A-B also include drive elements, e.g., linear motors, rotary motors coupled to a belt drive, etc., to control the motion of intermediate motion module 103 with respect to system frame 105 in the Yc direction. Intermediate motion module 103 also includes bearing elements, e.g., linear bearings, sets of roller bearings, etc., mounted between linear motion modules 102A-B and measurement chuck 106. The bearing elements constrain the motion of measurement chuck 106 with respect to linear motion modules 102A-B to the Xc direction. In addition, intermediate motion module 103 also include drive elements, e.g., linear motors, rotary motors coupled to a belt drive, etc., to control the motion of measurement chuck 106 with respect to linear motion modules 102A-B in the Xc direction. Typically positioning stage 101 is calibrated to map movements of measurement chuck 106 to the {Xsys,Ysys} coordinate frame. In this manner, calibrated positioning stage 101 controls the movement of measurement chuck 106 with respect to system frame 105 in the Xsys and Ysys directions.

In the embodiment depicted in FIGS. 3A-D, transfer robot 110 includes a linear motion module 118 including bearing elements, e.g., linear bearings, sets of roller bearings, etc., mounted between system frame 105 and robot base 111. The bearing elements constrain the motion of robot base 111 with respect to system frame 105 in one degree of freedom approximately aligned with the Xsys direction. In addition, linear motion module 118 also includes drive elements, e.g., linear motor, rotary motor coupled to a belt drive, etc., to control the motion of robot base 111 with respect to system frame 105 in the one degree of freedom approximately aligned with the Xsys direction. Transfer robot 110 also includes robot arm 112 coupled to robot base 111 by rotary actuator 115 at one end of robot arm 112. The opposite end of robot arm 112 is coupled to robot arm 113 by rotary actuator 114 at one end of robot arm 113. The opposite end of robot arm 113 is coupled to end-effector 117 by rotary actuator 116. The coordinated rotary motion of rotary actuators 114-116 controls the motion of end-effector 117 in a degree of freedom approximately aligned with the Ysys direction, and in a rotational degree of freedom of end-effector 117 about an axis of rotation of rotary actuator 115, which is parallel to the rotational axis, RZsys. Typically transfer robot 110 is calibrated to map movements of end effector 117 to the {Xsys,Ysys} coordinate frame. In this manner, calibrated transfer robot 110 controls the movement of end effector 117 with respect to system frame 105 in the Xsys and Ysys directions.

Load port 140 includes a front opening unified pod (FOUP) 141 loaded with processed wafers mounted to corresponding film frames. FIG. 3A depicts a wafer 123 mounted to a film frame 158 including a film 122 stretched across perimeter frame 121. As depicted in FIG. 3A, wafer 123 includes a notch feature, indicative of an orientation of wafer 123.

As depicted in FIG. 3A, coordinate frame {X_{W},Y_{W}} is attached to wafer 123 and the X_{W} axis is aligned with the notch structure 183 of wafer 123. Furthermore, coordinate frame {X_{FF},Y_{FF}} is attached to film frame 158. Before processing by the pre-alignment system, the location and orientation of wafer 123 and film frame 158 are unknown with respect to FOUP 141 and, more importantly, are unknown with respect to the system coordinate frame {Xsys,Ysys}.

Without pre-alignment, a film frame is simply placed on measurement chuck 106 by a pre-programed movement of transfer robot 110 from FOUP 141 to measurement chuck 106. In this example, the measurement system must undergo a time consuming exploration of the wafer surface to identify the location of wafer 123 with respect to the system coordinate frame before navigation and measurement can begin.

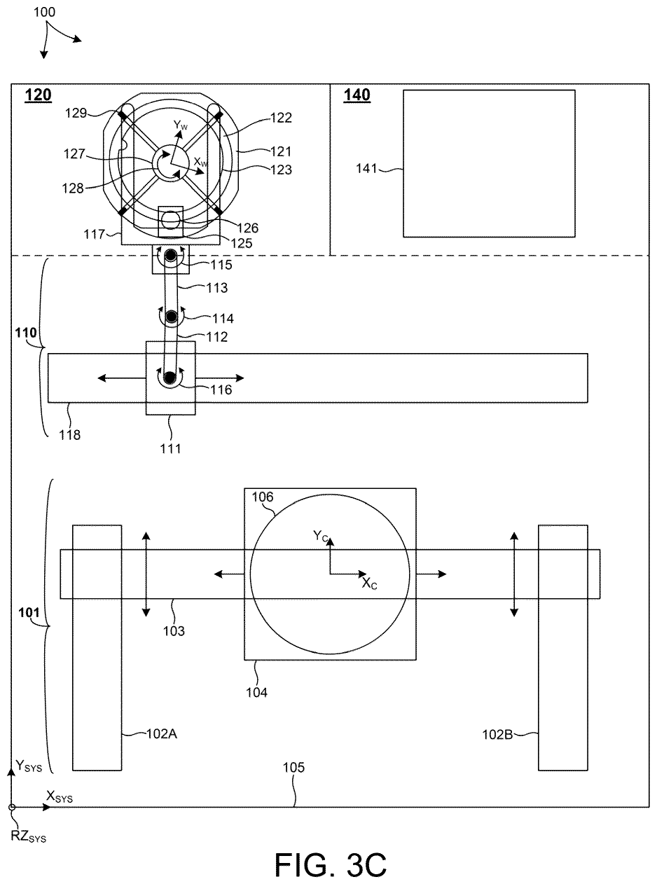

As depicted in FIGS. 3A-D and FIG. 4, measurement system 100 includes a pre-alignment system 120 that rapidly discovers the location of both film frame 158 and wafer 123 within the system coordinate frame and the orientation of wafer 123 within the system coordinate frame. In some embodiments, pre-alignment system 120 performs these measurements while the measurement system is measuring another wafer. This enables a significant increase in overall measurement system throughput.

FIG. 4 depicts a Film Frame (FF) pre-alignment system 120 in one embodiment. As depicted in FIG. 4, FF pre-alignment system 120 includes a pre-alignment frame 124, a FF chuck 127, a rotational actuator 128, a rotational measurement subsystem 156, an illumination subsystem 125, and an imaging subsystem 126.

In the embodiment depicted in FIG. 4, illumination subsystem 125 includes one or more light emitting diodes (LEDs), diffuser 151, and drive electronics (not shown). Illumination subsystem 125 is mechanically coupled to pre-alignment frame 124 and the illumination output 152 generated by illumination subsystem 125 is directed to the edge of wafer 123 and the inner edge of perimeter frame 121. Command signal 136 is communicated from computing system 130 to illumination subsystem 125. Command signal 136 specifies desired illumination properties of light emitted from illumination subsystem 125, e.g., desired luminous flux output, desired illumination spectrum, etc. In response, illumination subsystem 125 generates illumination light 152 in accordance with command signal 136. In the embodiment depicted in FIG. 4, illumination light 152 is transmitted through film 122, and is significantly blocked by wafer 123 and perimeter frame 121. Collected light 153 is transmitted through film 122, propagates through lens 154, and is projected onto an imaging detector of camera 126. The optical arrangement depicted in FIG. 4 is a bright field transmission imaging arrangement that provides a sharp image contrast at the edges of wafer 123 and the inner edge of perimeter frame 121. Camera 126 includes image capture and signal conditioning electronics that generate image signals 137 communicated to computing system 130.

As depicted in FIG. 4, FF chuck 127 supports perimeter frame 121 on pads 129. In the depicted embodiments, lift pins 155 are mechanically coupled to pre-alignment frame 124. In a lifting operational mode, lift pins 155 extend, engage with perimeter frame 121, and lift perimeter frame 121 off of pads 129 of FF chuck 127. In the fully lifted configuration, end effector 117 of transfer robot 110 is able to maneuver between perimeter frame 121 and FF chuck 127. With end effector 117 located between perimeter frame 121 and FF chuck 127, lift pins retract and place perimeter frame 121 onto end effector 117. End effector 117 is then able to move perimeter frame from pre-alignment system 120. Analogously, when loading perimeter frame 121 onto pre-alignment system 120, lift pins 155 begin in a retracted configuration while end effector 117 positions perimeter frame over FF chuck 127. After end effector 117 comes to a halt, lift pins 155 extend and lift perimeter frame 121 from end effector 117. After end effector 117 moves away from pre-alignment system 120, lift pins 155 retract and place perimeter frame 121 onto FF chuck 127. In this manner, lift pins 155 facilitate the loading and unloading of perimeter frame 121 in cooperation with transfer robot 110.

Although, the embodiment depicted in FIG. 4 include lift pins, in general, other configurations suitable for loading and unloading of perimeter frame 121 with respect to a pre-alignment system may be contemplated within the scope of this patent document. By way of non-limiting example, transfer robot 110 may also include an actuator capable of moving end effector 117 in the Z-direction, i.e., the direction perpendicular to the drawing sheet in FIGS. 3A-D. In these examples, lift pins are not required, as transfer robot 110 is able to place perimeter frame 121 onto FF chuck 127 and lift off perimeter frame 121 from FF chuck 127 by movement in the Z-direction. In another example, pre-alignment system 120 may include an actuator capable of moving FF chuck 127 in the Z-direction, i.e., the direction perpendicular to the drawing sheet in FIGS. 3A-D. In these examples, lift pins are not required, as pre-alignment system 120 is able to place perimeter frame 121 onto end effector 117 and lift off perimeter frame 121 from end effector 117 by movement in the Z-direction.

As depicted in FIG. 4, FF chuck 127 is mechanically constrained to rotate about axis of rotation, A, by one or more rotary bearings (not shown). Rotational actuator 128 drives the rotation of FF chuck 127 in response to command signals 135. In addition, rotational measurement subsystem 156 measures the rotational position of the FF chuck 127 with respect to pre-alignment frame 124. In some examples, rotational measurement subsystem includes a rotary encoder and signal conditioning electronics that generates rotational position signals 138 indicative of the rotational position of the FF chuck 127 with respect to pre-alignment frame 124.

As depicted in FIG. 4, camera 126, illumination subsystem 125, and rotary actuator 128 are mechanically coupled to pre-alignment frame 124. Furthermore, when integrated with measurement system 100, pre-alignment frame 124 is mechanically coupled to system frame 105. In some examples, pre-alignment system 120 is integrated with measurement system 100 by replacing a load port station of a measurement system with the pre-alignment system 120. However, in general, pre-alignment system 120 may be integrated with a measurement system in any suitable manner.

FIG. 4 is a simplified schematic view of one embodiment of a pre-alignment imaging system configured to image portions of perimeter frame 121, film 122, and wafer 123. The pre-alignment imaging system includes an illumination subsystem 125, a collection subsystem 154, and one or more detectors 126. The illumination subsystem 125 includes an illumination source 151 and all optical elements in the illumination optical path from the illumination source 151 to wafer 123. The collection subsystem 154 includes all optical elements in the collection optical path from wafer 123 to the detector 126. For simplification, some optical components of the system have been omitted. By way of example, folding mirrors, polarizers, beam forming optics, additional light sources, additional collectors, and detectors may also be included. All such variations are within the scope of the invention described herein.

As illustrated in FIG. 4, portions of wafer 123, film 122, and perimeter frame 121 are illuminated by a diffuse illumination light 152 generated by one or more illumination sources 151. Alternatively, the illumination subsystem 125 may be configured to direct the illumination light 152 to the specimen at an oblique angle of incidence. In some embodiments, subsystem 125 may be configured to direct light emitted from multiple illumination sources to wafer 123, film 122, and perimeter frame 121, at multiple angles of incidence, simultaneously or sequentially.

Illumination source 151 may include, by way of example, a laser, a supercontinuum laser, a diode laser, a helium neon laser, an argon laser, a solid state laser, a diode pumped solid state (DPSS) laser, a xenon arc lamp, a gas discharging lamp, an LED array, an incandescent lamp, a globar light source, etc. The light source may be configured to emit near monochromatic light or broadband light. In some embodiments, the illumination subsystem 125 may also include one or more spectral filters that may limit the wavelength of the light directed to the specimen. The one or more spectral filters may be bandpass filters and/or edge filters and/or notch filters. Illumination may be provided to the specimen over any suitable range of wavelengths. In some examples, the illumination light includes wavelengths ranging from 260 nanometers to 950 nanometers. In some examples, illumination light includes wavelengths greater than 950 nanometers (e.g., extending to 2,500 nanometers). In some embodiments, the illumination subsystem 125 may also include one or more polarization optics that control the polarization of the light directed to the specimen.

Collection subsystem 154 includes collection optics to collect the light scattered and/or reflected by portions of wafer 123, film 122, and perimeter frame 121, and focus that light onto detector 126. The output images 137 generated by detector 126 are communicated to computing system 130 for processing.

Collection optics 154 may be a lens, a compound lens, or any appropriate lens known in the art. Alternatively, any of collection optics 154 may be a reflective or partially reflective optical component, such as a mirror. Collection optics may be arranged at any appropriate collection angle. The collection angle may vary depending upon, for example, the angle of incidence and/or topographical characteristics of the specimen. In some embodiments, collection subsystem 154 also includes selectable collection polarization elements.

Detector 126 generally functions to convert the reflected and scattered light into an electrical signal, and therefore, may include substantially any photodetector known in the art. However, a particular detector may be selected for use within one or more embodiments of the invention based on desired performance characteristics of the detector, the type of wafer 123, film 122, and perimeter frame 121 to be imaged, and the configuration of the illumination. For example, if the amount of light available for imaging is relatively low, an efficiency enhancing detector such as a time delay integration (TDI) camera may increase the signal-to-noise ratio and throughput of the system. However, other detectors such as charge-coupled device (CCD) cameras, complementary metal-oxide semiconductor (CMOS) cameras, photodiodes, phototubes and photomultiplier tubes (PMTs) may be used, depending on the amount of light available for imaging and the type of imaging being performed.

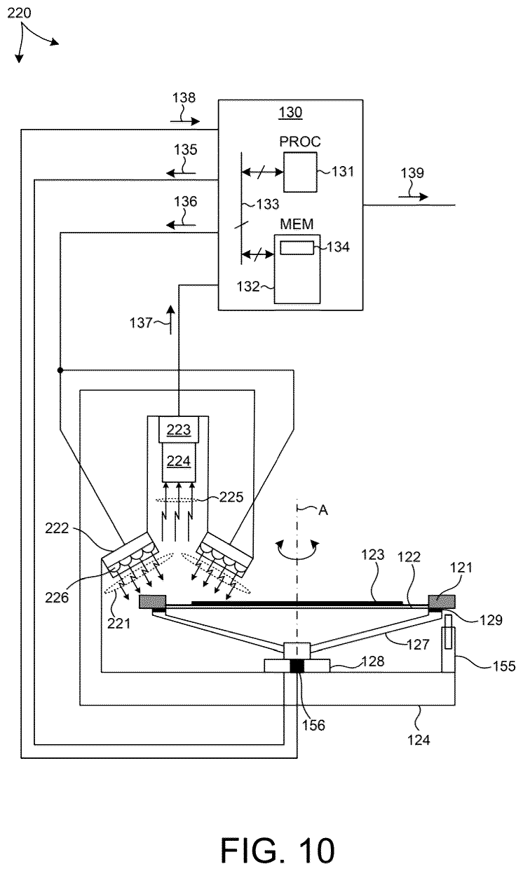

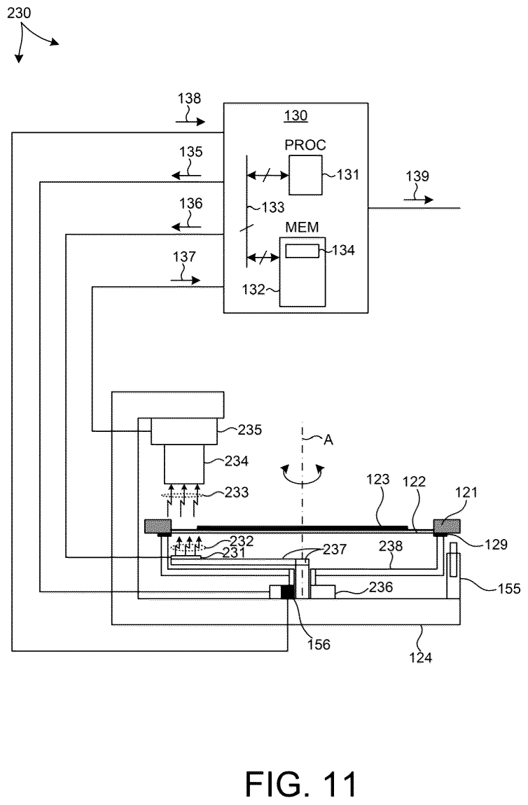

The pre-alignment imaging system can use various imaging modes, such as bright field and dark field modes. For example, in the embodiment depicted in FIG. 4, detector 126 generates a bright field transmission image. Similarly, in the embodiment depicted in FIG. 11, detector 235 generates a bright field transmission image. In these embodiments, some amount of light transmitted through film 122 scatters at a narrow angle and is collected by the collection subsystem. The collection subsystem includes an imaging lens, which in turn focuses the collected light onto the detector. In this manner a bright field image is generated by the detector. In some other embodiments, the detector generates dark field images by imaging scattered light collected at larger field angles. For example, in the embodiment depicted in FIG. 10, detector 223 generates a dark field reflection image. In these embodiments, some amount of light reflected from portions of perimeter frame 121 and wafer 123 scatters at a relatively large angle and is collected by the collection subsystem. The collection subsystem includes an imaging lens, which in turn focuses the collected light onto the detector. In this manner a dark field image is generated by the detector.

The pre-alignment imaging system also includes various electronic components (not shown) needed for processing the reflected and/or scattered signals detected by the detector. For example, the pre-alignment imaging system may include amplifier circuitry to receive output signals from the detector and to amplify those output signals by a predetermined amount and an analog-to-digital converter (ADC) to convert the amplified signals into a digital format suitable for use within processor 131. In one embodiment, the processor may be coupled directly to an ADC by a transmission medium. Alternatively, the processor may receive signals from other electronic components coupled to the ADC. In this manner, the processor may be indirectly coupled to the ADC by a transmission medium and any intervening electronic components.

In another aspect, image analysis is performed based on the images collected from portions of wafer 123, film 122, and perimeter frame 121 as described herein. In some examples, the location of wafer 123, the orientation of wafer 123, and the location of perimeter frame 121 with respect to a system coordinate frame are estimated based on an analysis of one or more collected images. In FIG. 4, output signals 139 are communicated from computing system 130 indicative of one or more of the estimated locations and orientations derived from one or more collected images as described herein.

In general, computing system 130 is configured to perform image analysis using images obtained from a detector. The computing system 130 may include any appropriate processor(s) known in the art. In addition, the computing system 130 may be configured to use any appropriate analysis algorithm or method known in the art. For example, the computing system 130 may use edge detection, die-to-database comparison, or a thresholding algorithm to detect features in collected images.

In addition, measurement system 100 may include peripheral devices useful to accept inputs from an operator (e.g., keyboard, mouse, touchscreen, etc.) and display outputs to the operator (e.g., display monitor). Input commands from an operator may be used by computing system 130 to adjust threshold values used to control illumination characteristics, collection characteristics, such as the field of view, and image processing parameters. The resulting images and detected features may be graphically presented to an operator on a display monitor.

The pre-alignment imaging system includes a processor 131 and an amount of computer readable memory 132. Processor 131 and memory 132 may communicate over bus 133. Memory 132 includes an amount of memory 134 that stores an amount of program code that, when executed by processor 131, causes processor 131 to execute the illumination and collection control, image collection, and image processing functionality described herein.

FIGS. 3A-D depict four different operational configurations of the semiconductor measurement system 100, respectively. As depicted in FIG. 3B, transfer robot 110 moves to unload film frame 158 from FOUP 141. In FIG. 3C, transfer robot 110 loads film frame 158 onto pre-alignment system 120. In FIG. 3D, transfer robot 110 loads film frame 158 onto measurement chuck 106 after pre-alignment measurements and corrections are performed.

In another aspect, a pre-alignment system is employed to estimate a location of a FF and a location and orientation of a wafer mounted to the FF with respect to a system coordinate frame based on one or more images captured by the pre-alignment system.

In one further aspect, computing system 130 executes a background masking algorithm to mask off background features from wafer 123 and background features of film frame 158. Exemplary background features include etch stains, debris, etc. present on film 122. Depending on image quality and wafer cleanliness, background masking is optional.

In another further aspect, computing system 130 executes a course edge detection algorithm on a collected image after background masking, if background masking is performed. The course edge detection algorithm will capture critical features such as the wafer edge and inner edge of the perimeter frame, and optionally, dicing lines. However, in addition to critical features, coarse edge detection may also detect spurious features such as non-circular edge structures, dicing residue, etc. In these examples, a secondary masking algorithm is executed by computing system 130 to mask off the spurious features.

In another further aspect, computing system 130 executes a fine edge detection algorithm on a collected image after secondary masking. The fine edge detection algorithm captures critical features such as the wafer edge and inner edge of the perimeter frame, and optionally, dicing lines with high spatial resolution with a minimum of spurious features. In general, masking and detection can be iterated until critical features are captures without spurious features.

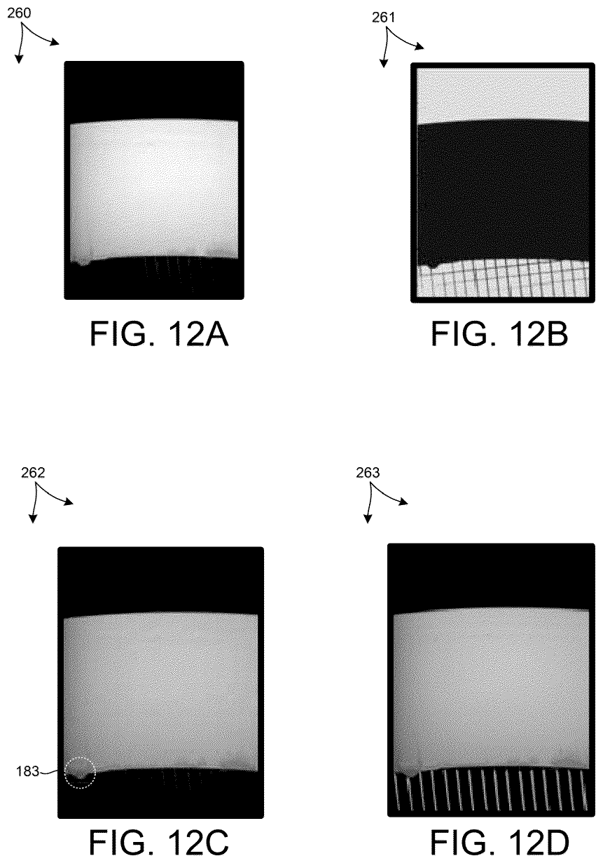

FIG. 12A is an image 260 illustrative of a whole wafer collected by camera 126 after background masking, course edge detection, secondary masking, and fine edge detection. As depicted in FIG. 12A, only circular segments of the wafer edge and inner frame edge are labeled successfully by the algorithm.

FIG. 12B is an image 261 illustrative of a diced wafer collected by camera 126 after background masking, course edge detection, secondary masking, and fine edge detection. As depicted in FIG. 12A, only circular segments of the wafer edge and inner frame edge and dicing lines are labeled by the fine edge detection algorithm.

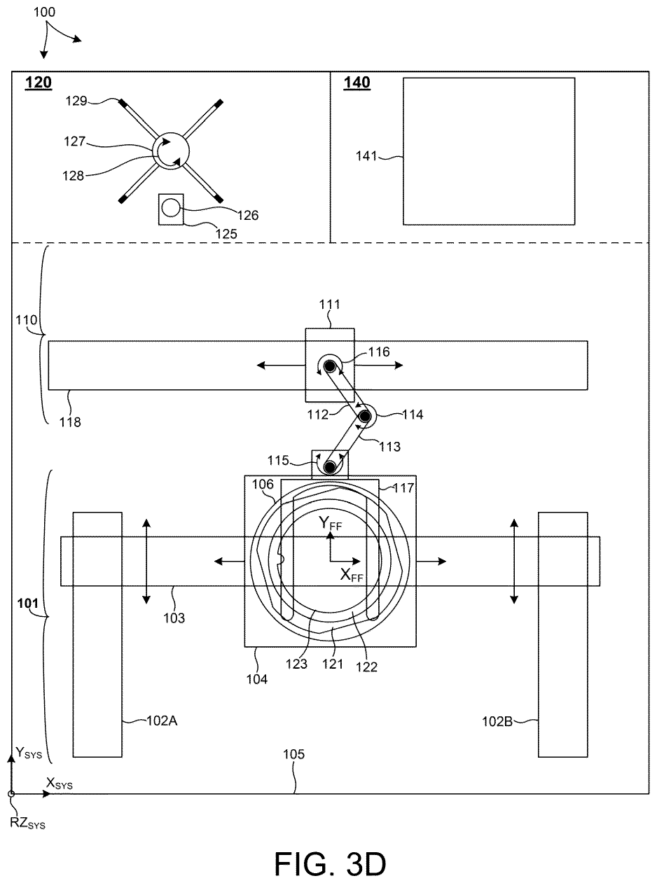

FIG. 5 is a diagram illustrative of an image 160 of a whole wafer collected by camera 126. The edge of wafer 123 and the inner edge of perimeter frame 121 are in the field of view of camera 126. Signals indicative of image 160 are communicated from camera 126 to computing system 130. In the example, depicted in FIG. 5, computing system 130 employs masking and edge detection algorithms to identify circular segments indicative of edge 162 of wafer 123 and the inner edge 161 of perimeter frame 161 in image 160.

In another further aspect, computing system 130 executes a circle fitting algorithm to the identified image segment 162 indicative of the edge of wafer 123 and to the identified image segment 161 indicative of the inner edge of perimeter frame 121. The circle fitting algorithm estimates the location of the geometric center of wafer 123, ^{IMG}(X_{WC}, Y_{WC})_{I}, in the space of image 160 and estimates the location of the geometric center of the inner edge of perimeter frame 121, ^{IMG}(X_{FFC}, Y_{FFC})_{I}, in the space of image 160 as depicted in FIG. 5.

In another further aspect, computing system 130 converts the estimated locations of the location of the geometric center of wafer 123, ^{IMG}(X_{WC}, Y_{WC})_{I}, and the location of the geometric center of the inner edge of perimeter frame 121, ^{IMG}(X_{FFC}, Y_{FFC})_{I}, from image space to the reference measurement system coordinate space, (X_{SYS}, Y_{SYS}) coordinate frame. Both the image space of camera 126, i.e., the pixels space associated with the field of view of camera 126, and the spaced defined by the measurement system coordinate frame are fixed relative to one another because camera 126 is rigidly mounted to system frame 105 (via pre-alignment frame 124). As a result the transformation from image space to the measurement system coordinate space is performed using a calibrated coordinate transformation matrix.

The calibrated coordinate transformation can be derived by using transfer robot 110 to move an object, e.g., film frame 158, end-effector 117 alone, etc., within the field of view of camera 126. The movements of transfer robot 110 are known in measurement system coordinate space, by calibration of transfer robot 110, itself. Thus, the location of the object moved by transfer robot 110 is known in measurement system coordinate space. For each known position of transfer robot 110, the object position in image space is calculated. The calculated values of object position in image space and corresponding known positions of transfer robot in measurement coordinate system space are then employed to generate a calibrated coordinate transformation matrix to transform locations in image space to locations in measurement system coordinate space.

After conversion, the estimated locations of the location of the geometric center of wafer 123 and the location of the geometric center of the inner edge of perimeter frame 121 are known in measurement system coordinate space, i.e., ^{SYS}(X_{WC}, Y_{WC})_{I} and ^{SYS}(X_{FFC}, Y_{FFC})_{I}.

In another further aspect, computing system 130 executes a pattern recognition algorithm to identify the location of a notch structure purposely integrated with the edge of wafer 123. In some examples, the pattern recognition algorithm includes a notch image kernel which is scanned across the image until a match with the highest matching score is obtained. FIG. 12C is an image 262 indicative of a notch structure 183 identified in image 262.

In another further aspect, computing system 130 determines the orientation of wafer 123 with respect to the measurement system coordinate space based on the location of the notch structure and an identified image segment indicative of the edge of wafer 123.

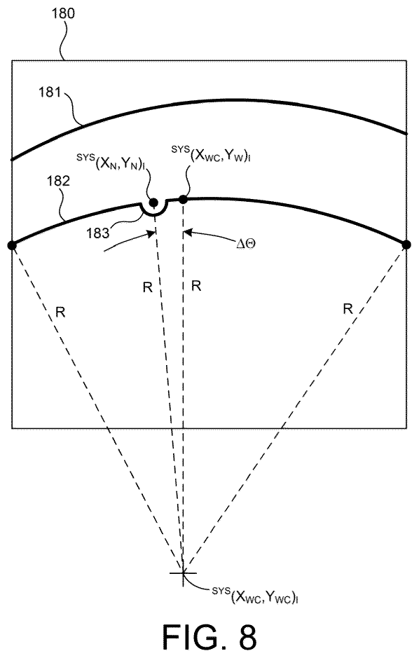

FIG. 8 is a diagram illustrative of an image 180 of a whole wafer collected by camera 126. The edge of wafer 123 and the inner edge of perimeter frame 121 are in the field of view of camera 126. Signals indicative of image 180 are communicated from camera 126 to computing system 130. In the example, depicted in FIG. 8, computing system 130 employs masking and edge detection algorithms to identify a circular segment indicative of edge 182 of wafer 123 and employs a pattern matching algorithm to identify the location, ^{IMG}(X_{N},Y_{N})_{I}, of notch structure 183 in image space. Computing system 130 executes a circle fitting algorithm to the identified image segment 182 indicative of the edge of wafer 123 to estimate the location of the geometric center of wafer 123, ^{IMG}(X_{WC}, Y_{WC})_{I}, in the space of image 180 as depicted in FIG. 8. The location of notch structure 183 and the location of the geometric center of wafer 123 are converted to measurement system coordinate space as described hereinbefore.

In a further aspect, computing system 130 computes the orientation of wafer 123 in measurement system coordinate space based on the identified locations of the geometric center of wafer 123 and notch structure 183. In the example depicted in FIG. 8, computing system 130 computes the angle, Δθ, between an axis passing through the geometric center of wafer 123 and the location, ^{SYS}(X_{N},Y_{N})_{I}, of notch structure 183, in measurement system coordinate space and an axis passing through the geometric center of wafer 123 and aligned with Y axis in measurement system coordinate space by trigonometric calculation.

In some other examples, the notch structure is not present or is significantly distorted by a dicing process such that the orientation angle cannot be determined. In these examples, computing system 130 computes the orientation of wafer 123 in measurement system coordinate space based on identified dicing lines on a diced or reconstructed wafer. FIG. 12D is an image 263 indicative of diced lines identified in image 263 in one example.

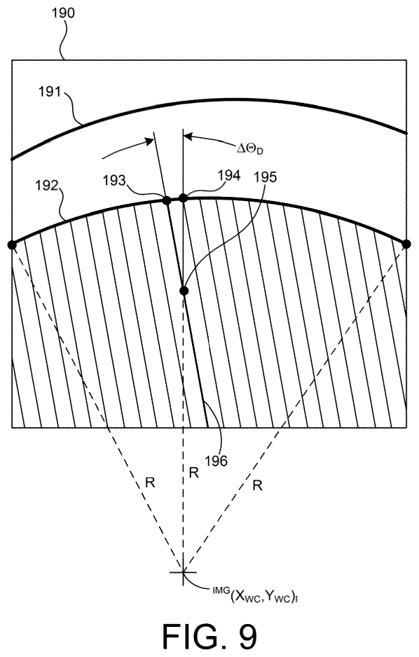

FIG. 9 is a diagram illustrative of an image 190 of a diced wafer collected by camera 126. The edge 192 of wafer 123 and the inner edge 191 of perimeter frame 121 are in the field of view of camera 126. Signals indicative of image 190 are communicated from camera 126 to computing system 130. In the example, depicted in FIG. 9, computing system 130 employs masking and edge detection algorithms to identify a circular segment indicative of edge 192 of wafer 123 and many dicing lines, for example, dicing line 196. Computing system 130 executes a circle fitting algorithm to the identified image segment 192 indicative of the edge of wafer 123 to estimate the location of the geometric center of wafer 123, ^{IMG}(X_{WC}, Y_{WC})_{I}, in the space of image 190 as depicted in FIG. 9. Computing system also identifies the location 194 on image segment 192 that shares the same X-coordinate value as the geometric center of wafer 123, the location 195 on dicing line 196 that shares the same X-coordinate value as the geometric center of wafer 123, and the location 193 on image segment 192 that intersects with dicing line 196. The locations 193-195 are converted to measurement system coordinate space as described hereinbefore. In the example depicted in FIG. 9, computing system 130 computes the angle, ΔθD, between dicing line 196 and an axis passing through the geometric center of wafer 123 and aligned with Y axis in measurement system coordinate space based on locations 193-195 by trigonometric calculation.

Although it is possible to estimate the position and orientation of wafer 123 in a measurement system coordinate space based on a single capture image as described hereinbefore, the accuracy of the location estimation depends heavily on the accuracy of the edge detection and fit quality.

In another further aspect, a pre-alignment system is employed to estimate a location of a FF and a location and orientation of a wafer mounted to the FF with respect to a system coordinate frame based on multiple images captured by the pre-alignment system. By averaging estimation results over many collected images, errors induced by difficult edge detection conditions, e.g., reconstructed wafers, and poor fit are minimized. In some examples, a pre-alignment system analyzes multiple images to estimate the location of a FF and a wafer in a measurement system coordinate frame within 50 micrometers, or less. In some examples, In some examples, a pre-alignment system analyzes multiple images to estimate the orientation of a wafer in a measurement system coordinate frame within 50 millidegrees, or less.

In preferred embodiments, a sequence of images are collected by camera 126 while rotational actuator 128 rotates film frame 121 and wafer 123. In some embodiments, image capture is triggered by the rotational position of FF chuck 127 as measured by rotational measurement subsystem 156. In one example, 50 images are collected over a full rotation of FF chuck 127, i.e., one image collected every 7.2 degrees.

In some examples, the center of wafer 123 and perimeter frame 121 are determined for each collected image as described hereinbefore. In another further aspect, a circle is fit to all of the determined locations of the center of wafer, and another circle is fit to all of the determined location of the center of film frame 158.

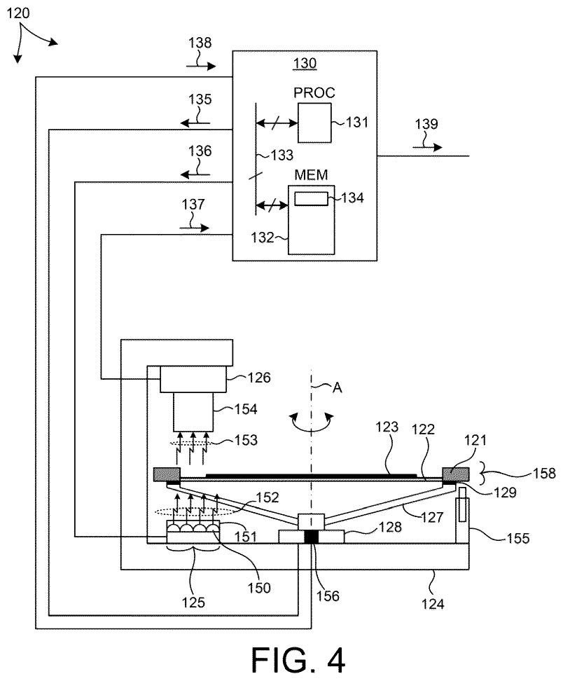

FIG. 6 is a simplified diagram 165 illustrative of the locations of center of wafer 123 in image space for N different collected images, where N is any positive, integer number greater than one. In the embodiment depicted in FIG. 6, computing system 130 fits a circle 166 to the N different determined locations of the center of wafer 123. The center of circle 166, ^{IMG}(X_{COR},Y_{COR}), corresponds to the estimated location of the center of rotation of pre-alignment chuck 127, i.e., the intersection of axis, A, depicted in FIG. 4 with wafer 123. Ideally, each determined location of the center of wafer 123 should lie on a circle around the center of rotation as wafer 123 is offset from the center of rotation by a fixed eccentricity. The distance between the center of rotation, ^{IMG}(X_{COR},Y_{COR}), and any point on circle 166 is an estimate of the offset between the center of rotation and the center of wafer 123 at the orientation angle associated with the selected point on the circle. For example, as depicted in FIG. 6, the estimated center of wafer 123 at the orientation angle associated with image 1 is offset from the center of rotation by a distance, (ΔX_{WC})₁, in the XSYS direction and (ΔY_{WC})₁, in the Y_{SYS} direction.

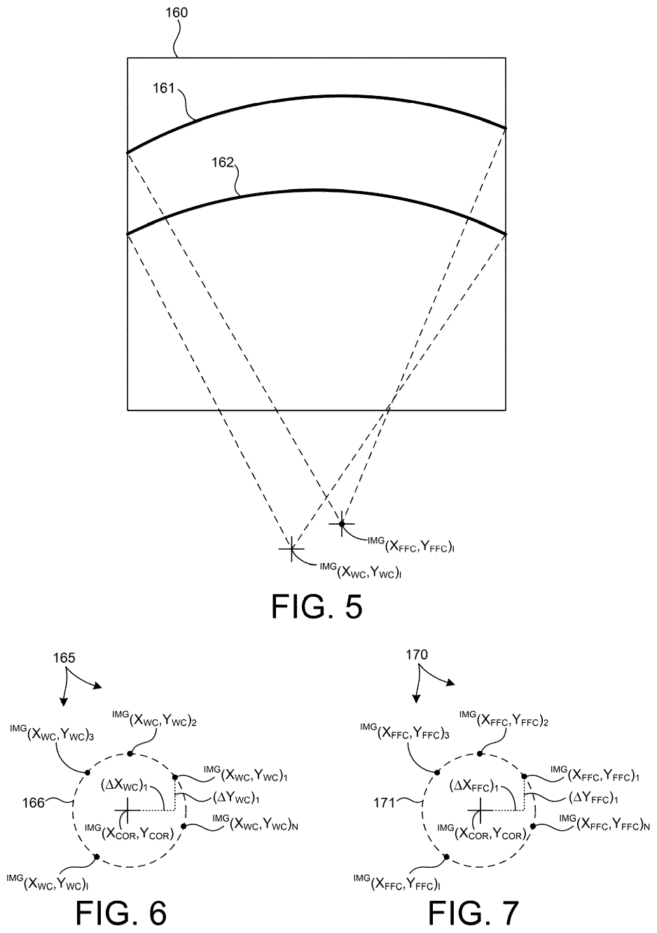

FIG. 7 is a simplified diagram 170 illustrative of the locations of center of film frame 158 in image space for N different collected images, where N is any positive, integer number greater than one. In the embodiment depicted in FIG. 7, computing system 130 fits a circle 171 to the N different determined locations of the center of film frame 158. The center of circle 171, ^{IMG}(X_{COR},Y_{COR}), corresponds to the estimated location of the center of rotation of pre-alignment chuck 127, i.e., the intersection of axis, A, depicted in FIG. 4 with wafer 123. Ideally, each determined location of the center of film frame 158 should lie on a circle around the center of rotation as film frame 158 is offset from the center of rotation by a fixed eccentricity. The distance between the center of rotation, ^{IMG}(X_{COR},Y_{COR}), and any point on circle 171 is an estimate of the offset between the center of rotation and the center of film frame 158 at the orientation angle associated with the selected point on the circle. For example, as depicted in FIG. 7, the estimated center of film frame 158 at the orientation angle associated with image 1 is offset from the center of rotation by a distance, (ΔX_{FFC})₁, in the X_{SYS} direction and (ΔY_{FFC})₁, in the Y_{SYS} direction.

In some examples, the orientation of wafer 123 with respect to a measurement system coordinate frame is determined by estimating the orientation of a notch structure or dicing lines from a number of collected images as described hereinbefore. The differences in orientation associated with rotation of pre-alignment chuck 127 are subtracted out of each result based on the known orientation measured by rotary encoder 156 and associated with each captured image. The resulting estimated values of orientation are then averaged to arrive at an estimated orientation of wafer 123 with respect to the measurement system coordinate frame.

With the orientation of wafer 123, the location of the geometric center of wafer 123, and the location of the geometric center of film frame 158 determined in measurement coordinate space by pre-alignment system 120, it is possible to locate film frame 158 and wafer 123 onto measurement chuck 106 at a known orientation and a known location in measurement coordinate space.

In a preferred embodiment, computing system 130 commands rotary actuator 128 to rotate film frame 158 to a desired final alignment angle of wafer 123 in measurement coordinate space based on the estimated alignment of wafer 123 in measurement coordinate space. In this manner, when transfer robot 110 transfers film frame 158 to measurement chuck 106, wafer 123 is already aligned with respect to the measurement system at the desired orientation. Similarly, computing system 130 commands transfer robot 110 to pick up film frame 158 and locate film frame 158 onto measurement chuck 106 such that the center of film frame 158 coincides with a particular location on measurement chuck 106, e.g., the center of measurement chuck 106. In this manner, the center of film frame 158 is located at a desired location on measurement chuck 106. In addition, computing system 130 computes the location of the center of wafer 123 with respect to the center of film frame 158 based on the difference between the estimated locations of the center of wafer 123 and the estimated location of the center of film frame 158 in measurement coordinate space. The location of the center of wafer 123 with respect to the center of film frame 158 is communicated to the measurement system, such that navigation on wafer 123 can be initiated immediately upon loading of film frame 158 on measurement chuck 106.

A pre-alignment system may optically configured in many different ways. Pre-alignment system 120 is provided by way of non-limiting example. However, many other optical configurations may be contemplated within the scope of this patent document.

FIG. 10 is a simplified diagram illustrative of another embodiment 220 of a pre-alignment system in another optical configuration. Like numbered elements illustrated in FIG. 10 and described with reference to FIG. 4 are analogous.

In the embodiment depicted in FIG. 10, the illumination subsystem 222 includes one or more light emitting diodes (LEDs) 226, diffuser 221, and drive electronics (not shown). In a preferred embodiment, LEDS 226 are arranged in a ring around the illuminated area of perimeter frame 121, film 122, and wafer 123. Illumination subsystem 222 is mechanically coupled to pre-alignment frame 124 and the illumination output 221 generated by illumination subsystem 226 is directed to the edge of wafer 123 and the inner edge of perimeter frame 121 from the top side of wafer 123. Command signal 136 is communicated from computing system 130 to illumination subsystem 222. Command signal 136 specifies desired illumination properties of light emitted from illumination subsystem 222, e.g., desired luminous flux output, desired illumination spectrum, etc. In response, illumination subsystem 222 generates illumination light 221 in accordance with command signal 136. In the embodiment depicted in FIG. 10, illumination light 221 is reflected from wafer 123 and perimeter frame 121, and is largely transmitted through film 122. Collected light 225 propagates through lens 224, and is projected onto an imaging detector of camera 223. The optical arrangement depicted in FIG. 10 is a bright field or dark field reflection imaging arrangement that provides a sharp image contrast at the edges of wafer 123 and the inner edge of perimeter frame 121. In a dark field configuration, illumination is provided from the ring of LEDs without a diffuser to generate a specific illumination angle incident on the illumination area. Camera 223 includes image capture and signal conditioning electronics that generate image signals 137 communicated to computing system 130.

FIG. 11 is a simplified diagram illustrative of another embodiment 230 of a pre-alignment system in another optical configuration. Like numbered elements illustrated in FIG. 11 and described with reference to FIG. 4 are analogous.

In the embodiment depicted in FIG. 11, the illumination subsystem 231 includes one or more light emitting diodes (LEDs), a waveguide back panel, and drive electronics. Illumination subsystem 231 is mechanically coupled to a support structure 237 that is fixed to pre-alignment frame 124. The illumination output 232 generated by illumination subsystem 231 is directed to the edge of wafer 123, film 122, and the inner edge of perimeter frame 121 from the bottom side of wafer 123. Command signal 136 is communicated from computing system 130 to illumination subsystem 231. Command signal 136 specifies desired illumination properties of light emitted from illumination subsystem 231, e.g., desired luminous flux output, desired illumination spectrum, etc. In response, illumination subsystem 231 generates illumination light 232 in accordance with command signal 136. In the embodiment depicted in FIG. 11, illumination light 232 is largely transmitted through film 122 and largely reflected from wafer 123 and perimeter frame 121. Collected light 233 propagates through lens 234, and is projected onto an imaging detector of camera 235. The optical arrangement depicted in FIG. 11 is a bright field transmission imaging arrangement that provides a sharp image contrast at the edges of wafer 123 and the inner edge of perimeter frame 121. Camera 235 includes image capture and signal conditioning electronics that generate image signals 137 communicated to computing system 130.

In the embodiment depicted in FIG. 11, a hollow-type rotary motor 236 is employed to rotate pre-alignment chuck 238, while support structure 237 remains fixed to pre-alignment frame 124. In the embodiment depicted in FIG. 11, illumination subsystem 231 is located between pre-alignment chuck 238 and wafer 123. This enables illumination that is not interrupted by the structure of pre-alignment chuck 238 and enables the illumination source to be located much closer to wafer 123.

In some other embodiments, a pre-alignment system includes multiple illumination sources and corresponding cameras arranged around the perimeter of wafer 123. In this manner, images can be collected simultaneously for a number of different orientation angles, thus increasing throughput. Furthermore, the angular range over which wafer 123 must be rotated is reduced.

In some other embodiments, a pre-alignment system includes a camera with a larger field of view, allowing captured images to include both the inner and outer edge of perimeter frame 121.

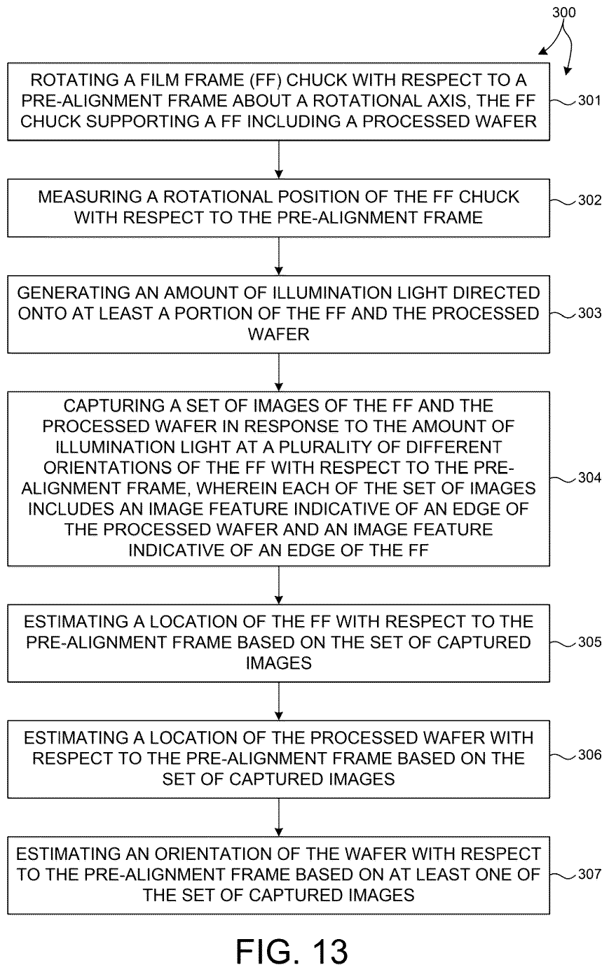

FIG. 13 illustrates a flowchart of an exemplary method 300 useful for pre-alignment of film frames in at least one novel aspect. In some non-limiting examples, pre-alignment systems 120, 220, and 230 described with reference to FIGS. 4, 10, and 11, respectively, are configured to implement method 300. However, in general, the implementation of method 300 is not limited by the specific embodiments described herein.

In block 301, a Film Frame (FF) chuck is rotated with respect to a pre-alignment frame about a rotational axis. The FF chuck supports a FF including a processed wafer.

In block 302, a rotational position of the FF chuck with respect to the pre-alignment frame is measured.

In block 303, an amount of illumination light is generated and directed onto at least a portion of the FF and the processed wafer.

In block 304, a set of images of the FF and the processed wafer is captured in response to the amount of illumination light at a plurality of different orientations of the FF with respect to the pre-alignment frame. Each of the set of images includes an image feature indicative of an edge of the processed wafer and an image feature indicative of an edge of the FF.

In block 305, a location of the FF with respect to the pre-alignment frame is estimated based on the set of captured images.

In block 306, a location of the processed wafer with respect to the pre-alignment frame is estimated based on the set of captured images.

In block 307, an orientation of the wafer with respect to the pre-alignment frame is estimated based on at least one of the set of captured images

In one or more exemplary embodiments, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general purpose or special purpose computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

Although certain specific embodiments are described above for instructional purposes, the teachings of this patent document have general applicability and are not limited to the specific embodiments described above. Accordingly, various modifications, adaptations, and combinations of various features of the described embodiments can be practiced without departing from the scope of the invention as set forth in the claims.

What is claimed is:

1. A Film Frame (FF) pre-alignment system, comprising:
a pre-alignment frame;
a FF chuck configured to support a FF including a processed wafer;
a rotational actuator configured to rotate the FF chuck with respect to the pre-alignment frame about a rotational axis;
a rotational measurement subsystem configured to measure a rotational position of the FF chuck with respect to the pre-alignment frame;
an illumination subsystem including at least one illumination source configured to direct an amount of illumination light onto at least a portion of the FF and the processed wafer;
an imaging subsystem including at least one imaging detector configured to capture a set of images of the FF and the processed wafer at a plurality of different orientations of the FF with respect to the pre-alignment frame, wherein a field of view of the imaging subsystem includes an edge of the processed wafer and an edge of the FF; and
a computing system configured to:
estimate a location of the FF with respect to the pre-alignment frame based on the set of captured images;
estimate a location of the processed wafer with respect to the pre-alignment frame based on the set of captured images; and
estimate an orientation of the wafer with respect to the pre-alignment frame based on at least one of the set of captured images.

2. The FF pre-alignment system of claim 1, the computing system further configured to:
estimate a position offset between the estimated location of the FF and the rotational axis; and
estimate a position offset between the estimated location of the processed wafer and the estimated location of the FF.

3. The FF pre-alignment system of claim 2, the computing system further configured to:
communicate the estimated position offset between the estimated location of the FF and the estimated location of the processed wafer to a measurement system.

4. The FF pre-alignment system of claim 1, the rotational actuator further configured to rotate the processed wafer such that the processed wafer is oriented at a desired orientation with respect to the pre-alignment frame.

5. The FF pre-alignment system of claim 1, wherein the estimating of the orientation of the processed wafer with respect to the pre-alignment frame involves estimating an orientation of a wafer notch feature of the processed wafer with respect to the pre-alignment frame.

6. The FF pre-alignment system of claim 1, wherein the estimating of the orientation of the processed wafer with respect to the pre-alignment frame involves estimating an orientation of an array of die with respect to the pre-alignment frame.

7. The FF pre-alignment system of claim 1, further comprising:
a set of lift pins configured to lower the processed wafer onto the FF chuck and lift the processed wafer off of the FF chuck.

8. The FF pre-alignment system of claim 1, the illumination subsystem including an array of Light Emitting Diodes (LEDs).

9. The FF pre-alignment system of claim 1, wherein the at least one detector is a CCD camera.

10. The FF pre-alignment system of claim 1, wherein the processed wafer is a whole wafer, a diced wafer, or a reconstructed wafer.

11. A method comprising:
rotating a Film Frame (FF) chuck with respect to a pre-alignment frame about a rotational axis, the FF chuck supporting a FF including a processed wafer;
measuring a rotational position of the FF chuck with respect to the pre-alignment frame;
generating an amount of illumination light directed onto at least a portion of the FF and the processed wafer;
capturing a set of images of the FF and the processed wafer in response to the amount of illumination light at a plurality of different orientations of the FF with respect to the pre-alignment frame, wherein each of the set of images includes an image feature indicative of an edge of the processed wafer and an image feature indicative of an edge of the FF;
estimating a location of the FF with respect to the pre-alignment frame based on the set of captured images;
estimating a location of the processed wafer with respect to the pre-alignment frame based on the set of captured images; and
estimating an orientation of the wafer with respect to the pre-alignment frame based on at least one of the set of captured images.

12. The method of claim 11, further comprising:
estimating a position offset between the estimated location of the FF and the rotational axis; and
estimating a position offset between the estimated location of the processed wafer and the estimated location of the FF.

13. The method of claim 12, further comprising:
communicating the estimated position offset between the estimated location of the FF and the estimated location of the processed wafer to a measurement system.

14. The method of claim 11, further comprising:
rotating the processed wafer such that the processed wafer is oriented at a desired orientation with respect to the pre-alignment frame.

15. The method of claim 11, wherein the estimating of the orientation of the processed wafer with respect to the pre-alignment frame involves estimating an orientation of a wafer notch feature of the processed wafer with respect to the pre-alignment frame.

16. The method of claim 11, wherein the estimating of the orientation of the processed wafer with respect to the pre-alignment frame involves estimating an orientation of an array of die with respect to the pre-alignment frame.

17. The method of claim 11, further comprising:
lowering the processed wafer onto the FF chuck; and
lifting the processed wafer off of the FF chuck.

18. The method of claim 11, wherein the processed wafer is a whole wafer, a diced wafer, or a reconstructed wafer.

19. A Film Frame (FF) pre-alignment system, comprising:
a pre-alignment frame;
a FF chuck configured to support a FF including a processed wafer;
a rotational actuator configured to rotate the FF chuck with respect to the pre-alignment frame about a rotational axis;
a rotational measurement subsystem configured to measure a rotational position of the FF chuck with respect to the pre-alignment frame;
an illumination subsystem including at least one illumination source configured to direct an amount of illumination light onto at least a portion of the FF and the processed wafer;
an imaging subsystem including at least one imaging detector configured to capture a set of images of the FF and the processed wafer at a plurality of different orientations of the FF with respect to the pre-alignment frame, wherein a field of view of the imaging subsystem includes an edge of the processed wafer and an edge of the FF; and
a non-transitory, computer-readable medium comprising instructions that, when executed by one or more processors, cause the one or more processors to:
estimate a location of the FF with respect to the pre-alignment frame based on the set of captured images;
estimate a location of the processed wafer with respect to the pre-alignment frame based on the set of captured images; and
estimate an orientation of the wafer with respect to the pre-alignment frame based on at least one of the set of captured images.

20. The FF pre-alignment system of claim 19, the non-transitory, computer-readable medium further comprising instructions that, when executed by one or more processors, cause the one or more processors to:
estimate a position offset between the estimated location of the FF and the rotational axis; and
estimate a position offset between the estimated location of the processed wafer and the estimated location of the FF.
